(19) United States
(12) Patent Application Publication
(10) Pub. No.: US 2026/0344144 A1
(43) Pub. Date: Oct. 29, 2026

(54) DISPLAY PANEL, ELECTRONIC DEVICE INCLUDING THE SAME, AND MANUFACTURING METHOD OF THE DISPLAY PANEL

(71) Applicant: Samsung Display Co., Ltd., Yongin-si (KR)

(72) Inventors: YESEUL NA, Yongin-si (KR); JINGOO KANG, Yongin-si (KR); DONGHOON KWAK, Yongin-si (KR); KYONGSUB KIM, Yongin-si (KR); ARONG LEE, Yongin-si (KR)

(21) Appl. No.: 19/446,632

(22) Filed: Jan. 12, 2026

(30) Foreign Application Priority Data
Apr. 28, 2025 (KR) 10-2025-0055449

(51) Int. Cl. H10H 29/37; H10H 20/812; H10H 29/01; H10H 29/853

(52) U.S. Cl. CPC H10H 29/37; H10H 20/812; H10H 29/012; H10H 29/853

(57) ABSTRACT

A display panel includes: a substrate having a display area and a non-display area defined therein; a circuit element layer on the substrate; a display element layer on the circuit element layer; and an encapsulation structure on the display element layer, wherein the display element layer includes: a pixel defining layer having a light emitting opening defined therein; and a light emitting element including an anode, a hole transport area, a light emitting layer including a quantum dot, an electron transport area, and a cathode sequentially stacked one above another, wherein the pixel defining layer includes a first layer and a second layer on the first layer and including a material different from a material of the first layer, and wherein the second layer includes water (H₂O) and a hydrogen ion (H⁺).

### CROSS-REFERENCE TO RELATED APPLICATIONS

The present application claims priority to and the benefit of Korean Patent Application No. 10-2025-0055449, filed on Apr. 28, 2025, in the Korean Intellectual Property Office, the entire disclosure of which is incorporated herein reference.

### BACKGROUND

Aspects of some embodiments of the present disclosure described herein relate to a display panel, an electronic device, and a manufacturing method of the display panel.

Various multimedia electronic devices, such as televisions, mobile phones, tablet computers, car navigation devices, game machines, and wearable devices, may include a display panel for displaying image information.

The display panel may include a light emitting element that includes a luminescent material, such as an organic compound or a quantum dot, in a light emitting layer located between electrodes facing each other and emits light by a self-luminous method.

The self-luminous light emitting element has a structure in which a pixel itself emits light without a separate light source and has the advantages of a thin thickness, a high contrast ratio, and a fast response speed. Accordingly, the self-luminous light emitting element may be applied to various electronic devices, and the performance of the display panel including the corresponding light emitting element is a factor that may influence the quality of an entire electronic device.

Therefore, in order to relatively improve the quality of the display panel, a technology for increasing the light efficiency of the light emitting element and relatively improving the lifetime of the element to maintain initial characteristics even during long-term operation may be desired.

The above information disclosed in this Background section is only for enhancement of understanding of the background and therefore the information discussed in this Background section does not necessarily constitute prior art.

### SUMMARY

Aspects of some embodiments of the present disclosure described herein relate to a display panel, an electronic device, and a manufacturing method of the display panel, and for example, to a display panel having relatively improved efficiency and lifetime by healing defects in light emitting elements, an electronic device including the display panel, and a method for manufacturing the display panel.

Aspects of some embodiments of the present disclosure include a display panel having excellent light efficiency and relatively improved lifetime characteristics and an electronic device including the display panel.

According to some embodiments, a display panel includes a substrate having a display area and a non-display area defined therein, a circuit element layer on the substrate, a display element layer on the circuit element layer, and an encapsulation structure on the display element layer. According to some embodiments, the display element layer includes a pixel defining layer having a light emitting opening defined therein and a light emitting element including an anode, a hole transport area, a light emitting layer including a quantum dot, an electron transport area, and a cathode sequentially stacked one above another. According to some embodiments, the pixel defining layer includes a first layer and a second layer that is on the first layer and that includes a material different from a material of the first layer, and the second layer includes water (H₂O) and a hydrogen ion (H⁺).

According to some embodiments, the second layer may include a liquid-repellent material.

According to some embodiments, the liquid-repellent material may include a fluorine-based material.

According to some embodiments, the sum of a thickness of the hole transport area and a thickness of the anode may be smaller than a thickness of the first layer.

According to some embodiments, the light emitting layer may be spaced apart from the second layer.

According to some embodiments, at least a portion of the light emitting layer may make contact with the second layer.

According to some embodiments, the hole transport area may include a hole injection layer and a hole transport layer on the hole injection layer. According to some embodiments, the electron transport area may include an electron transport layer and an electron injection layer on the electron transport layer. According to some embodiments, the electron transport layer may make contact with the second layer.

According to some embodiments, the light emitting opening may include a plurality of light emitting openings, and the plurality of light emitting openings may include a first light emitting opening that defines a first light emitting area that emits light of a first color, a second light emitting opening that defines a second light emitting area that emits light of a second color different from the first color, and a third light emitting opening that defines a third light emitting area that emits light of a third color different from the first color and the second color. According to some embodiments, the light emitting element may include a plurality of light emitting elements, and the plurality of light emitting elements may include a first light emitting element in the first light emitting opening, a second light emitting element in the second light emitting opening, and a third light emitting element in the third light emitting opening. According to some embodiments, a hole transport area of the first light emitting area may be in the first light emitting opening, a hole transport area of the second light emitting area may be in the second light emitting opening, and a hole transport area of the third light emitting area may be in the third light emitting opening.

According to some embodiments, the display panel may further include first to third color filters arranged to correspond to the first to third light emitting elements, respectively.

According to some embodiments, the display panel may further include a sealing member between the substrate and the encapsulation structure to couple the substrate and the encapsulation structure.

According to some embodiments, the encapsulation structure may make contact with the cathode.

According to some embodiments, a method for manufacturing a display panel includes an operation of forming a circuit element layer on a substrate, an operation of forming an anode on the circuit element layer, an operation of forming, on the anode, a pixel defining layer including a first layer, and a second layer on the first layer and including water (H₂O) and a hydrogen ion (H⁺), an operation of forming a light emitting opening by patterning the pixel defining layer, an operation of sequentially forming a hole transport area, a light emitting layer including a quantum dot, and an electron transport area on the anode, an operation of performing positive aging of the electron transport area, and an operation of forming a cathode on the electron transport area. According to some embodiments, in the operation of performing the positive aging the electron transport area, the water (H₂O) and the hydrogen ion (H⁺) move from the second layer to the electron transport area.

According to some embodiments, the operation of performing the positive aging the electron transport area may include an operation of applying a solution including an acid material to the pixel defining layer and the electron transport area and an operation of applying heat to the pixel defining layer such that the water (H₂O) and the hydrogen ion (H⁺) included in the pixel defining layer move toward the electron transport layer.

According to some embodiments, the acid material may include at least one of citric acid, malic acid, or ascorbic acid.

According to some embodiments, the hole transport area and the light emitting layer may be formed through an inkjet process.

According to some embodiments, the second layer may be formed by depositing or coating a liquid-repellent material.

According to some embodiments, an electronic device includes a display module including a display panel and a processor that provides image data to the display module. According to some embodiments, the display panel includes a substrate having a display area and a non-display area defined therein, a circuit element layer on the substrate, a display element layer on the circuit element layer, and an encapsulation structure on the display element layer. According to some embodiments, the display element layer includes a pixel defining layer having a light emitting opening defined therein and a light emitting element including an anode, a hole transport area, a light emitting layer including a quantum dot, an electron transport area, and a cathode sequentially stacked one above another. According to some embodiments, the pixel defining layer includes a first layer being lyophilic and a second layer on the first layer, the second layer being liquid repellent. The second layer includes water (H₂O) and a hydrogen ion (H⁺).

According to some embodiments, the second layer may include a fluorine-based material.

According to some embodiments, the sum of a thickness of the hole transport area and a thickness of the anode may be smaller than a thickness of the first layer.

According to some embodiments, the hole transport area may include a hole injection layer and a hole transport layer on the hole injection layer. According to some embodiments, the electron transport area may include an electron transport layer and an electron injection layer on the electron transport layer. According to some embodiments, the electron transport layer may make contact with the second layer.

### BRIEF DESCRIPTION OF THE DRAWINGS

The above and other aspects and features of some embodiments of the present disclosure will become more apparent by describing in more detail aspects of some embodiments thereof with reference to the accompanying drawings.

FIG. 1 is a block diagram of an electronic device according to some embodiments.

FIG. 2 illustrates schematic views of various electronic devices according to some embodiments.

FIG. 3 is a perspective view illustrating an electronic device according to some embodiments.

FIG. 4 is a perspective view of a display device according to some embodiments of the present disclosure.

FIG. 5A is a sectional view of the display device according to some embodiments of the present disclosure.

FIG. 5B is a sectional view of a display device according to some embodiments of the present disclosure.

FIG. 6 is a sectional view of the display device taken along the line I-I’ of FIG. 4.

FIG. 7 is an enlarged sectional view of a display element layer of a display panel.

FIG. 8 is an enlarged sectional view of the display element layer of the display panel.

FIG. 9 is an enlarged sectional view of the display element layer of the display panel.

FIGS. 10A-10I are sectional views illustrating some of the operations of a display panel manufacturing method according to some embodiments of the present disclosure.

### DETAILED DESCRIPTION

Various changes can be made to the present disclosure, and various embodiments of the present disclosure may be implemented. Thus, specific embodiments are illustrated in the drawings and described as examples herein. However, it should be understood that the present disclosure is not to be construed as being limited thereto and covers all modifications, equivalents, and alternatives falling within the spirit and scope of the present disclosure.

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the spirit and scope of embodiments according to the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

The expression “directly located” used herein may mean that there is no additional layer, film, area, or plate between one portion, such as a layer, a film, an area, or a plate, and another portion. For example, the expression “directly located” may mean that two layers or two members are located without an additional member such as an adhesive member therebetween.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, aspects of a display device according to some embodiments will be described with reference to the accompanying drawings.

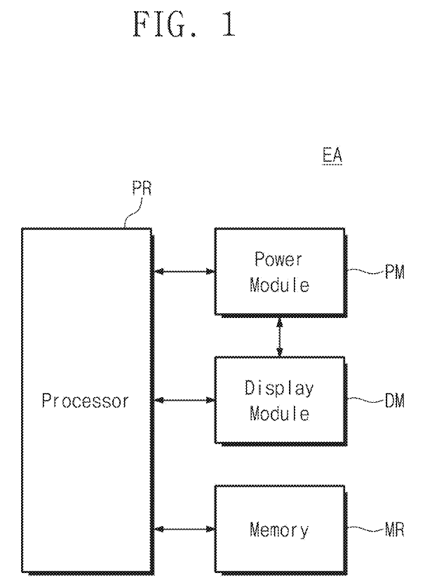

FIG. 1 is a block diagram of an electronic device according to some embodiments.

Referring to FIG. 1, the electronic device EA according to some embodiments may include a display module DD, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

Data information required for operation of the processor PR or the display module DD may be stored in the memory MR. When the processor PR executes an application stored in the memory MR, an image data signal and/or an input control signal may be transferred to the display module DD, and the display module DD may process the provided signal and may output image information through a display screen. The display module DD may include a display panel that displays an image.

The power module PM may include a power conversion module. The power conversion module may convert power supplied by a power supply module, such as a power adapter or a battery device, to generate power required for operation of the electronic device EA.

At least one of the components of the electronic device EA described above may be included in a display module and a display device including the same according to embodiments to be described below. In addition, some of the separate modules functionally included in one module may be included in the display device, and the others may be provided separately from the display device. For example, the display device may include the display module DD, and the processor PR, the memory MR, and the power module PM may be provided in the form of other devices in the electronic device EA rather than the display device.

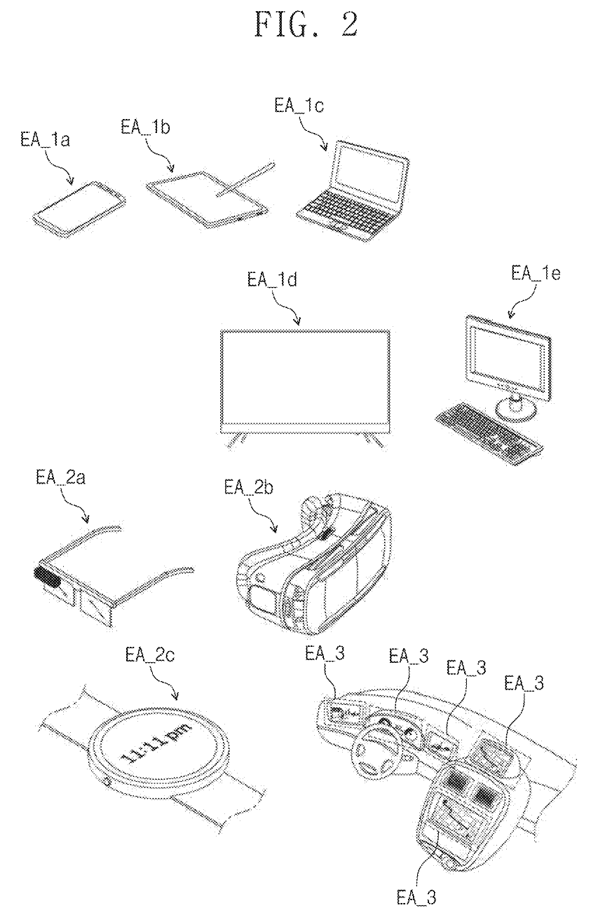

FIG. 2 illustrates schematic views of embodiments of various electronic devices.

Referring to FIG. 2, the various electronic devices including a display module according to some embodiments may include not only electronic devices for displaying images, such as a smart phone EA_1a, a tablet PC EA_1b, a laptop computer EA_1c, a TV EA_1d, and a desk monitor EA_1e, but also wearable electronic devices, such as smart glasses EA_2a, a head mounted display EA_2b, and a smart watch EA_2c, and vehicle electronic devices EA_3, such as center information displays (CID) located on an instrument panel, a center fascia, and a dashboard of a vehicle and a room mirror display.

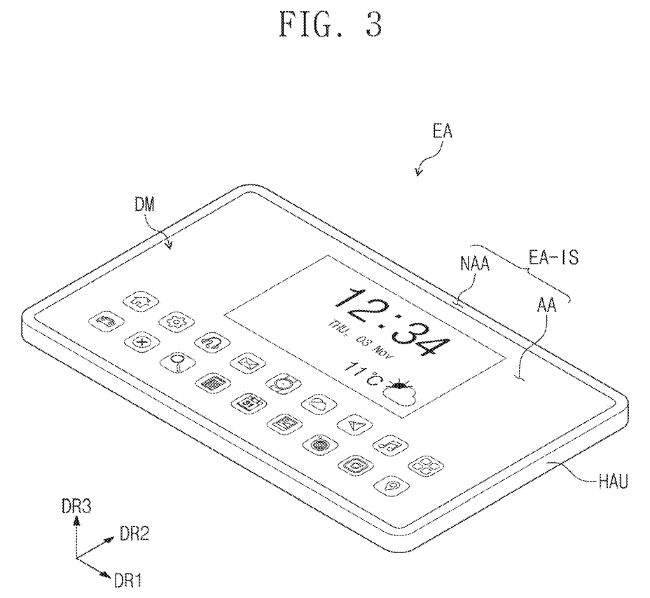

FIG. 3 is a perspective view illustrating an electronic device according to some embodiments.

The electronic device EA according to some embodiments may include a display device DM that displays an image through a display surface EA-IS. The display device DM may be accommodated in a housing HAU. The electronic device EA may include the display device DM and a controller that controls operation of the display device DM.

The display surface EA-IS of the electronic device EA, when viewed from above a plane, may have a rectangular shape with long sides extending in a first direction DR1 and short sides extending in a second direction DR2 crossing the first direction DR1. However, without being limited thereto, the display surface EA-IS may have various shapes such as a circular shape and a polygonal shape.

In this specification, a third direction DR3 may be defined as a direction perpendicular (or substantially perpendicular) to a plane defined by the first direction DR1 and the second direction DR2. Front surfaces (or, upper surfaces) and rear surfaces (or, lower surfaces) of members constituting the electronic device EA may be opposite each other in the third direction DR3, and the normal directions of the front surfaces and the rear surfaces may be parallel (or substantially parallel) to the third direction DR3. The separation distances between the front surfaces and the rear surfaces that are defined in the third direction DR3 may correspond to the thicknesses of the members.

The expression “when viewed from above the plane” used herein may mean that it is viewed in the third direction DR3. That is, the expression “when viewed from above the plane” may be described based on the plane defined by the first direction DR1 and the second direction DR2. The expression “on a cross-section” used herein may mean that it is viewed in the first direction DR1 or the second direction DR2. Meanwhile, the directions indicated by the first to third directions DR1, DR2, and DR2 may be relative concepts and may be changed to other directions.

In FIG. 3, a tablet terminal is illustrated as an example of the electronic device EA. Electronic modules, a camera module, and a power module mounted on the main board, together with the display device DM, may be located in the bracket/housing HAU to constitute the tablet terminal. Meanwhile, embodiments are not limited thereto, and the display device DM and a display panel according to some embodiments to be described below may be applied to small and medium-sized electronic devices, such as a personal computer, a notebook computer, a personal digital assistant, a car navigation unit, a game machine, a smart phone, a tablet computer, a smart watch, and a camera, as well as large electronic devices such as a television, a monitor, and a billboard. However, these are merely illustrative, and the display device DM according to some embodiments may be employed as other electronic devices without departing from the spirit and scope of the present disclosure. Meanwhile, the electronic device EA including the display device DM may be referred to as a display device.

According to some embodiments, the electronic device EA including the display device DM having a flat display surface is illustrated, but the present disclosure is not limited thereto. The electronic device EA may include a curved display surface or a three-dimensional display surface. For example, the three-dimensional display surface may include a plurality of display areas indicating different directions and may include a bent display surface. The electronic device EA according to some embodiments may be a flexible electronic device. The flexible electronic device may be a foldable electronic device capable of being folded.

As illustrated in FIG. 3, the display surface EA-IS includes an active area AA where an image is displayed and a bezel area NAA adjacent to (e.g., in a periphery or outside a footprint of) the active area AA. The bezel area NAA is an area where images are not displayed. In FIG. 3, icon images are illustrated as an example of the image. The active area AA may be referred to as a display area of the display device DM, and the bezel area NAA may be referred to as a non-display area of the display device DM.

As illustrated in FIG. 3, the active area AA may have a quadrangular (or substantially quadrangular) shape. The "substantially quadrangular shape" includes not only a quadrangular shape in a mathematical sense, but also a quadrangular shape in which the boundaries of curves rather than vertexes are defined in the vertex areas (or the corner areas).

The bezel area NAA may surround (e.g., in a periphery or outside a footprint of) the active area AA. However, without being limited thereto, the shape of the bezel area NAA may be modified. For example, the bezel area NAA may be located on only one side of the active area AA.

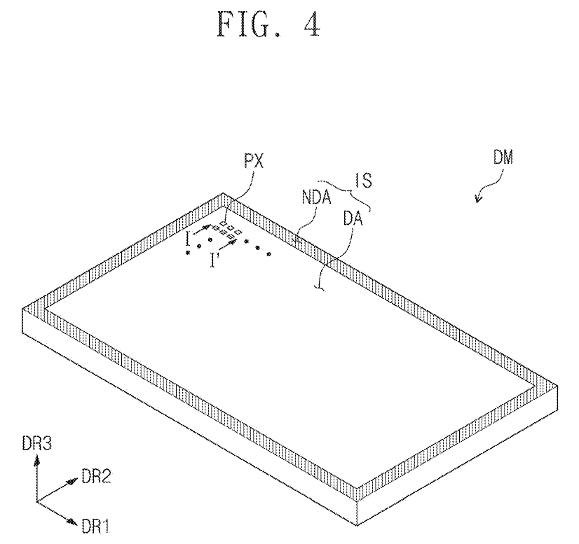

FIG. 4 is a perspective view of the display device according to some embodiments of the present disclosure.

Referring to FIG. 4, the display device DM may include a display surface IS. The display device DM may display an image through the display surface IS. The display surface IS of the display device DM may correspond to the display surface EA-IS of the electronic device EA.

The display surface IS may include a display area DA and a non-display area NDA. A plurality of pixels PX may be located in the display area DA.

Referring to FIG. 4, the pixels PX may be arranged in a stripe form when viewed from above the plane. That is, the plurality of pixels PX may be arranged in the first direction DR1 or the second direction DR2. However, embodiments are not limited thereto, and the pixels PX may be arranged in a PENTILE^{TM} form or a Diamond Pixel^{TM} form.

In addition, although the pixels PX are all illustrated as having similar planar areas in FIG. 4, embodiments are not limited thereto, and the pixels PX may have different planar areas depending on the wavelength range of emitted light.

The pixels PX may not be located in the non-display area NDA of the display surface IS. The non-display area NDA may surround the display area DA. However, without being limited thereto, according to some embodiments of the present disclosure, the non-display area NDA may be omitted or may be located on only one side of the display area DA.

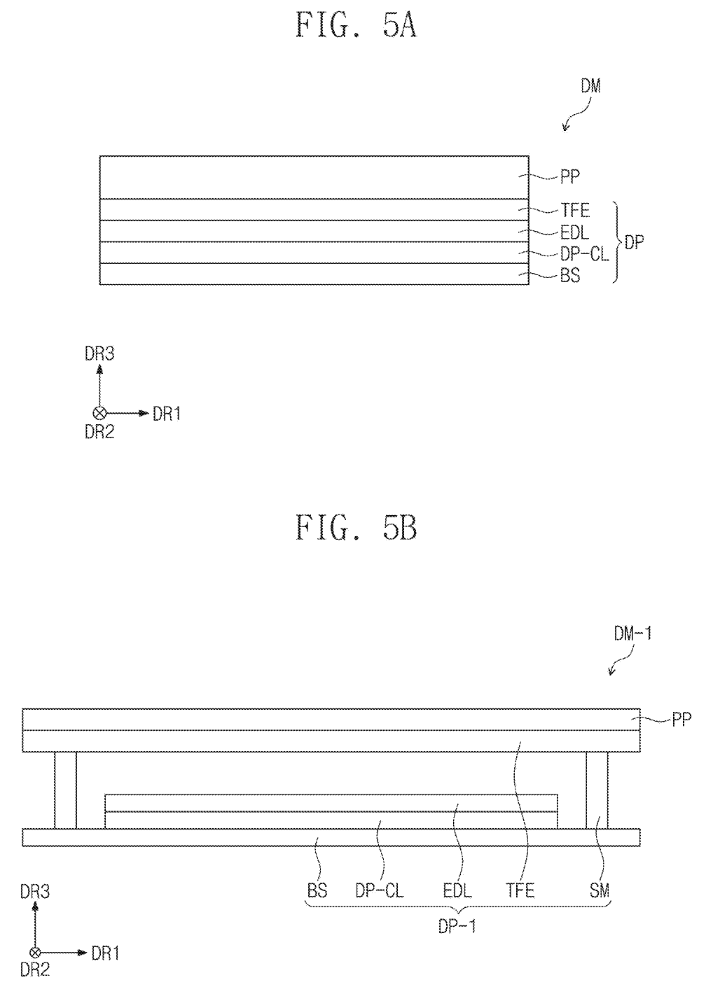

FIG. 5A is a sectional view of the display device according to some embodiments of the present disclosure. FIG. 5B is a sectional view of a display device according to some embodiments of the present disclosure.

Referring to FIG. 5A, the display device DM may include a display panel DP and an optical member PP. The display panel DP may generate image data or display images. The display panel DP may be included in the electronic device EA (refer to FIG. 3) and may display images. The display panel DP may be an emissive display panel. For example, according to some embodiments of the present disclosure, the display panel DP may include an inorganic light emitting material such as quantum dots.

The display panel DP may include a substrate BS, a circuit element layer DP-CL, a display element layer EDL, and an encapsulation structure TFE sequentially stacked in the third direction DR3.

The substrate BS may include at least one plastic film. The substrate BS may include a plastic substrate, a glass substrate, a metal substrate, or an organic/inorganic composite substrate as a flexible substrate.

The circuit element layer DP-CL may be located on the substrate BS. The circuit element layer DP-CL may include a plurality of transistors. Each of the transistors may include a control electrode, an input electrode, and an output electrode. For example, the circuit element layer DP-CL may include a switching transistor and a driving transistor to drive light emitting elements of the display element layer EDL.

The display element layer EDL may be located on the circuit element layer DP-CL. The display element layer EDL may include a plurality of quantum-dot emitting diodes. The display element layer EDL may further include an organic layer or an inorganic layer such as a pixel defining layer.

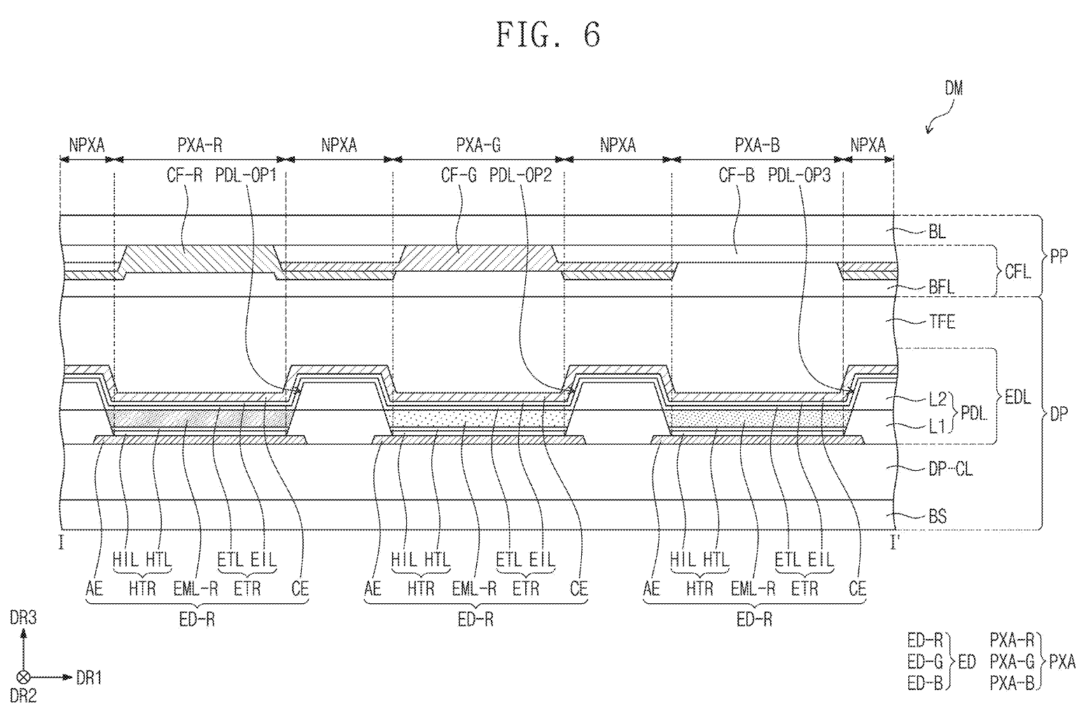

The encapsulation structure TFE may seal the display element layer EDL. The encapsulation structure TFE may be directly located on the display element layer EDL. For example, the encapsulation structure TFE may make contact with a cathode CE (refer to FIG. 6) of the display element layer EDL. The encapsulation structure TFE may cover light emitting elements ED (refer to FIG. 6) located in the display element layer EDL. The encapsulation structure TFE may overlap the display area DA and at least a portion of the non-display area NDA. The encapsulation structure TFE may include a stack structure of an inorganic layer, an organic layer, and an inorganic layer. The encapsulation structure TFE may protect the display element layer EDL from foreign matter such as moisture, oxygen, and dust particles.

The optical member PP may be located on the display panel DP and may control light reflected from the display panel DP due to external light. Meanwhile, this is illustrative, and in the display device DM according to some embodiments of the present disclosure, the optical member PP may be omitted.

Referring to FIG. 5B, according to some embodiments of the present disclosure, a display panel DP-1 may further include a sealing member SM. In this case, an encapsulation structure TFE may be spaced apart from the display panel DP-1 on the cross-section. An inert gas may be filled between the encapsulation structure TFE and a display element layer EDL. The sealing member SM may be located between a substrate BS and the encapsulation structure TFE to couple the substrate BS and the encapsulation structure TFE. A display device according to some embodiments of the present disclosure may include various forms of encapsulation structures and is not limited to any one embodiment.

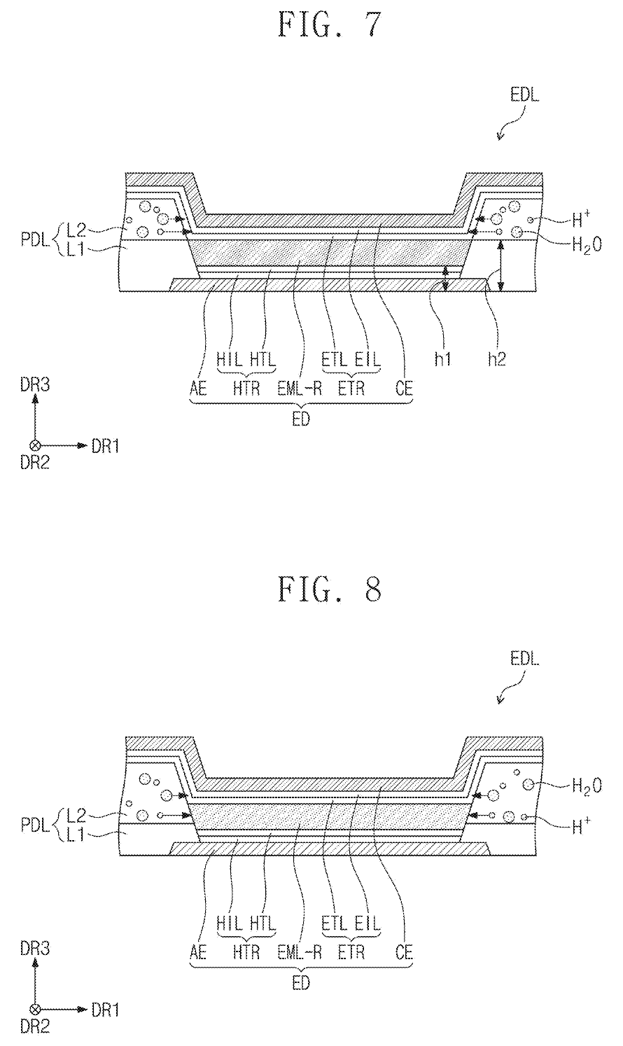

FIG. 6 is a sectional view of the display device taken along the line I-I’ of FIG. 4. FIG. 7 is an enlarged sectional view of the display element layer of the display panel. In the description with reference to FIGS. 6 and 7, components identical/similar to the components described with reference to FIGS. 4-5B will be assigned with identical/similar reference numerals, and some repetitive description may be omitted.

Referring to FIG. 6, the display device DM may include a plurality of light emitting areas PXA and a non-light emitting area NPXA located around the light emitting areas PXA. The light emitting areas PXA may include first to third light emitting areas PXA-R, PXA-G, and PXA-B. The first to third light emitting areas PXA-R, PXA-G, and PXA-B may be areas that are distinguished from one another when viewed from above the plane and that emit light in different wavelength ranges.

The non-light emitting area NPXA may set the boundaries between the first to third light emitting areas PXA-R, PXA-G, and PXA-B. The non-light emitting area NPXA may surround each of the first to third light emitting areas PXA-R, PXA-G, and PXA-B. In the non-light emitting area NPXA, a structure for preventing or reducing color mixing between the first to third light emitting areas PXA-R, PXA-G, and PXA-B, for example, a pixel defining layer PDL may be arranged to overlap the non-light emitting area NPXA.

The first to third light emitting areas PXA-R, PXA-G, and PXA-B may be areas distinguished from one another by the pixel defining layer PDL. The non-light emitting area NPXA may be an area between the first to third light emitting areas PXA-R, PXA-G, and PXA-B adjacent to one another and may be an area corresponding to the pixel defining layer PDL.

The first to third light emitting areas PXA-R, PXA-G, and PXA-B may be areas where light generated by first to third light emitting elements ED-R, ED-G, and ED-B is emitted. The first to third light emitting areas PXA-R, PXA-G, and PXA-B may be distinguished from one another depending on the colors of the light generated by the first to third light emitting elements ED-R, ED-G, and ED-B. For example, in the display device DM according to some embodiments, the first light emitting area PXA-R may be a red-light emitting area, the second light emitting area PXA-G may be a green-light emitting area, and the third light emitting area PXA-B may be a blue-light emitting area.

Meanwhile, although three light emitting areas PXA-R, PXA-G, and PXA-B distinguished from one another are illustrated in FIG. 6, embodiments are not limited thereto, and the display device DM according to some embodiments may include four or more light emitting areas having different emission characteristics.

The display element layer EDL may include the pixel defining layer PDL and the plurality of light emitting elements ED.

A plurality of light emitting openings PDL-OP may be defined in the pixel defining layer PDL. The plurality of light emitting openings PDL-OP may include a first light emitting opening PDL-OP1 that defines the first light emitting area PXA-R, a second light emitting opening PDL-OP2 that defines the second light emitting area PXA-G, and a third light emitting opening PDL-OP3 that defines the third light emitting area PXA-B. The light emitting openings PDL-OP of the pixel defining layer PDL may expose at least portions of anodes AE.

The pixel defining layer PDL may include a first layer L1 and a second layer L2 located on the first layer L1. The first layer L1 and the second layer L2 may include different materials.

The first layer L1 may include an inorganic material. For example, the first layer L1 may include an inorganic material having hydrophilic characteristics, such as silicon nitride (SiNx), silicon oxide (SiOx), or silicon oxy nitride (SiOxNy).

The second layer L2 may include a liquid-repellent material and may include water (H₂O) and hydrogen ions (H⁺). Because the second layer L2 includes the liquid-repellent material, the water (H₂O) and the hydrogen ions (H⁺) in the second layer L2 may be easily moved to an electron transport layer ETL in contact with the second layer L2 in a positive aging operation to be described below. Thus, electron transport characteristics may be relatively improved, or an interface stabilization effect may be obtained. Detailed description thereabout will be given below.

The plurality of light emitting elements ED may include the first light emitting element ED-R, the second light emitting element ED-G, and the third light emitting element ED-B that emit light in different wavelength ranges. For example, the first light emitting element ED-R may emit red light, the second light emitting element ED-G may emit green light, and the third light emitting element ED-B may emit blue light.

Each of the light emitting elements ED may include the anode AE, a hole transport area HTR, a light emitting layer EML-R, EML-G, or EML-B including quantum dots, an electron transport area ETR, and the cathode CE sequentially stacked one above another.

The anodes AE may be separately located to correspond to the light emitting areas PXA-R, PXA-G, and PXA-B, respectively. Each of the anodes AE may be a transmissive electrode, a transflective electrode, or a reflective electrode. The anode AE may include a single-layer structure or a multi-layer structure. The anode AE may include a plurality of layers including ITO and Ag. For example, the anode AE may include a layer including ITO (hereinafter, referred to as the lower ITO layer), a layer that is located on the lower ITO layer and that includes Ag (hereinafter, referred to as the Ag layer), and a layer that is located on the Ag layer and that includes ITO (hereinafter, referred to as the upper ITO layer). However, without being limited thereto, the anode AE may be provided as a single layer.

The light emitting layers EML-R, EML-G, and EML-B of the first to third light emitting areas ED-R, ED-G, and ED-B may be located in the first to third light emitting openings PDL-OP1, PDL-OP2, and PDL-OP3, respectively. The light emitting layers EML-R, EML-G, and EML-B may include quantum dots.

The quantum dots may be selected from a Group II-VI compound, a Group I-II-VI compound, a Group II-IV-VI compound, a Group I-II-IV-VI compound, a Group III-VI compound, a Group I-III-VI compound, a Group III-V compound, a Group III-II-V compound, a Group II-IV-V compound, a Group IV-VI compound, a Group IV element, a Group IV compound, and combinations thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and mixtures thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures thereof. Meanwhile, the Group II-VI compound may further include a Group I metal and/or a Group IV element. The Group I-II-VI compound may be selected from CuSnS or CuZnS, and ZnSnS may be selected as the Group II-IV-VI compound. The Group I-II-IV-VI compound may be selected from a quaternary compound selected from the group consisting of Cu2ZnSnS2, Cu2ZnSnS4, Cu2ZnSnSe4, Ag2ZnSnS2, and mixtures thereof.

The Group III-VI compound may include a binary compound such as In2S3 or In2Se3, a ternary compound such as InGaS3 or InGaSe3, or any combination thereof.

The Group I-III-VI compound may be selected from a ternary compound selected from the group consisting of AgInS, AgInS2, CuInS, CuInS2, AgGaS2, CuGaS2 CuGaO2, AgGaO2, AgAlO2, and mixtures thereof or a quaternary compound such as AgInGaS2 or CuInGaS2.

The Group III-V compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. Meanwhile, the Group III-V compound may further include a Group II metal. For example, InZnP may be selected as the Group III-II-V compound.

The Group II-IV-V compound may be a ternary compound selected from the group consisting of ZnSnP, ZnSnP2, ZnSnAs2, ZnGeP2, ZnGeAs2, CdSnP2, and CdGeP2, and mixtures thereof.

The Group IV-VI compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The Group IV element may be selected from the group consisting of Si, Ge, and a mixture thereof. The Group IV compound may be a binary compound selected from the group consisting of SiC, SiGe, and a mixture thereof.

In this case, the binary compound, the ternary compound, or the quaternary compound may exist in the particle at a uniform concentration or may exist in the same particle with partially different concentration distribution. The quantum dots may have a core/shell structure in which one quantum dot surrounds another quantum dot. In the core/shell structure, the concentration of elements existing in the shell may have a concentration gradient in which the concentration gradually decreases toward the core.

In some embodiments, the quantum dots may have a core-shell structure that includes a core including the aforementioned nanocrystals and a shell surrounding the core. The shell of each quantum dot may serve as a protective layer for maintaining semiconductor characteristics by preventing or reducing chemical modification of the core and/or a charging layer for imparting electrophoretic characteristics to the quantum dot. The shell may include a single layer or multiple layers. The shell may be illustrated by metal or non-metal oxide, a semiconductor compound, or a combination thereof.

The shell may include a material different from that of the core. For example, the core may include a first semiconductor nanocrystal, and the shell may include a second semiconductor nanocrystal different from the first semiconductor nanocrystal. Alternatively, the shell may include metal or non-metal oxide. The shell may include metal or non-metal oxide, a semiconductor nanocrystal, or a combination thereof.

The shell may be formed of a single material, but may be formed to have a concentration gradient. For example, the shell may have a concentration gradient in which the concentration of the second semiconductor nanocrystal existing in the shell gradually decreases toward the core and the concentration of the first semiconductor nanocrystal included in the core increases. Meanwhile, the sell may have a multi-layer structure including different materials.

For example, the metal or non-metal oxide may include a binary compound such as SiO2, Al2O3, TiO2, ZnO, MnO, Mn2O3, Mn3O4, CuO, FeO, Fe2O3, Fe3O4, CoO, Co3O4, or NiO or a ternary compound such as MgAl2O4, CoFe2O4, NiFe2O4, or CoMn2O4, but the present disclosure is not limited thereto.

The semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb, but the present disclosure is not limited thereto.

The quantum dots may have a full width at half maximum (FWHM) of a light emission wavelength spectrum that is 45 nanometers (nm) (or about 45 nm) or less, preferably 40 nm (or about 40 nm) or less, and more preferably 30 nm (or about 30 nm) or less and may relatively improve color purity or color reproduction in the range. Furthermore, light emitted through the quantum dots may be emitted in all directions, and thus a wide viewing angle may be relatively improved.

The form of the quantum dots is not particularly limited to a form generally used in the related art. For example, a nanoparticle, a nanotube, a nanowire, a nanofiber, or a nanoplatelet particle that has a spherical, pyramidal, multi-arm, or cubic shape may be used.

The quantum dots may adjust the colors of emitted light depending on the particle sizes. Accordingly, the quantum dots may have various light emission colors such as blue, red, and green. As the particle sizes of the quantum dots are decreased, light in a short wavelength range may be emitted. For example, among quantum dots having the same core, the particle size of a quantum dot that emits green light may be smaller than the particle size of ae quantum dot that emits red light. In addition, among the quantum dots having the same core, the particle size of a quantum dot that emits blue light may be smaller than the particle size of the quantum dot that emits green light. However, embodiments are not limited thereto, and in the quantum dots having the same core, the particle sizes may be adjusted depending on the material and thickness of the shell.

Meanwhile, when the quantum dots have various light emission colors such as blue, red, and green, quantum dots having different emission colors may have different core materials.

The quantum dots may adjust the colors of emitted light depending on the particle sizes. Accordingly, the quantum dots may have various light emission colors such as blue, red, and green. As the particle sizes of the quantum dots are decreased, light in a short wavelength range may be emitted. For example, the particle size of the quantum dot that emits green light may be smaller than the particle size of the quantum dot that emits red light, and the particle size of the quantum dot that emits blue light may be smaller than the particle size of the quantum dot that emits green light.

The cathode CE may be located on the electron transport area ETR. The cathode CE may be provided as a common layer in all of the light emitting areas PXA-R, PXA-G, and PXA-B.

The hole transport areas HTR may be located between the anodes AE and the light emitting layers EML-R, EML-G, and EML-B. The hole transport areas HTR may be separately arranged to independently correspond to the light emitting areas PXA-R, PXA-G, and PXA-B, respectively. For example, the hole transport area HTR of the first light emitting element ED-R may be located in the first light emitting opening PDL-OP1, the hole transport area HTR of the second light emitting element ED-G may be located in the second light emitting opening PDL-OP2, and the hole transport area HTR of the third light emitting element ED-B may be located in the third light emitting opening PDL-OP3.

The electron transport area ETR may be located between the light emitting layers EML-R, EML-G, and EML-B and the cathode CE. The electron transport area ETR may be provided as a common layer in all of the light emitting areas PXA-R, PXA-G, and PXA-B.

The hole transport areas HTR and the electron transport area ETR may each include a plurality of sub-functional layers. For example, each of the hole transport areas HTR may include a hole injection layer HIL and a hole transport layer HTL located on the hole injection layer HIL as sub-functional layers, and the electron transport area ETR may include the electron transport layer ETL and an electron injection layer EIL located on the electron transport layer ETL as sub-functional layers. Meanwhile, without being limited thereto, the hole transport area HTR may further include an electron blocking layer as a sub-functional layer, and the electron transport area ETR may further include a hole blocking layer as a sub-functional layer.

According to some embodiments, the display element layer EDL may further include a capping layer. The capping layer may be located on the cathode CE. The capping layer may include a single layer or multiple layers. The capping layer may be provided as a common layer in all of the light emitting areas PXA-R, PXA-G, and PXA-B.

According to some embodiments of the present disclosure, the display device DM may further include the optical member PP located on the display panel DP. The optical member PP may include a base substrate BL and a color filter layer CFL.

The base substrate BL may be a member that provides a base surface on which the color filter layer CFL is located. The base substrate BL may be a glass substrate, a metal substrate, or a plastic substrate. However, embodiments are not limited thereto, and the base substrate BL may be an inorganic layer, an organic layer, or a composite layer.

The color filter layer CFL may include first to third color filters CF-R, CF-G, and CF-B. The first to third color filters CF-R, CF-G, and CF-B may be arranged to correspond to the first to third light emitting elements ED-R, ED-G, and ED-B, respectively. For example, the first color filter CF-R may be a red filter, the second color filter CF-G may be a green filter, and the third color filter CF-B may be a blue filter. The first to third color filters CF-R, CF-G, and CF-B may be arranged to correspond to the first to third pixel areas PXA-R, PXA-G, and PXA-B, respectively.

In addition, the plurality of color filters CF-R, CF-G, and CF-B that transmit light of different colors may be arranged to overlap each other in correspondence to the non-light emitting area NPXA located between the pixel areas PXA-R, PXA-G, and PXA-B. The plurality of color filters CF-R, CF-G, and CF-B may be arranged to overlap each other in the third direction DR3, which is the thickness direction, so that the boundaries between the adjacent pixel areas PXA-R, PXA-G, and PXA-B may be distinguished from each other. Accordingly, a light blocking effect of external light in the areas where the plurality of color filters overlap each other may be increased, and thus the structure formed by the plurality of color filters overlapping each other may have a function similar to that of a black matrix. The overlapping structure of the plurality of color filters CF-R, CF-G, and CF-B may have a function of preventing or reducing color mixing.

Each of the first to third color filters CF-R, CF-G, and CF-B may include a photosensitive polymer resin and a pigment or dye. The first color filter CF-R may include a red pigment or a blue dye, the second color filter CF-G may include a green pigment or a green dye, and the third color filter CF-B may include a blue pigment or a red dye. However, embodiments are not limited thereto, and the third color filter CF-B may not include a pigment or dye. The third color filter CF-B may include a photosensitive polymer resin and may not include a pigment or dye. The third color filter CF-B may be transparent. The third color filter CF-B may be formed of a transparent photosensitive resin.

The color filter layer CFL may further include a buffer layer BFL. For example, the buffer layer BFL may be a protective layer that protects the first to third color filters CF-R, CF-G, and CF-B. The buffer layer BFL may be an inorganic layer including at least one of silicon nitride, silicon oxide, or silicon oxy nitride. The buffer layer BFL may include a single layer or a plurality of layers.

In addition, the first color filter CF-R and the second color filter CF-G may be yellow filters. The first color filter CF-R and the second color filter CF-G may be integrally provided without being distinguished from each other.

According to some embodiments, the color filter layer CFL may further include a light blocking part. The light blocking part may be a black matrix. The light blocking part may include an organic light blocking material or an inorganic light blocking material that includes a black pigment or a black dye. The light blocking part may prevent or reduce a light leakage phenomenon and may demarcate the boundaries between the adjacent color filters CF-R, CF-G, and CF-B.

In addition, unlike in FIG. 6, the optical member PP of the display device DM according to some embodiments may not include the color filter layer CFL.

Referring to FIG. 7, the sum h1 of the thickness of the hole transport area HTR and the thickness of the anode AE may be smaller than the thickness h2 of the first layer L1. That is, the hole transport area HTR may be spaced apart from the second layer L2. According to some embodiments, the hole transport area HTR and the light emitting layer EML-R, EML-G, or EML-B may make contact with the first layer L1, and the electron transport layer ETL may make contact with the second layer L2.

As described above, the first layer L1 may include an inorganic material having hydrophilic characteristics, and the second layer L2 may include a liquid-repellent material. In this case, the liquid-repellent material may be a fluorine-based material.

According to the present disclosure, in order to stabilize hole injection characteristics by applying a positive voltage during initial operation of an element and to correct initial characteristics of a light emitting element, the positive aging operation may be performed in a display panel formation process. In this process, the hydrogen ions (H⁺) and the water (H₂O) remaining in the pixel defining layer may be moved by an electric field and may penetrate a sensitive organic layer such as the hole transport layer, which may cause degradation or damage to the element.

According to some embodiments of the present disclosure, the hole transport area HTR and the light emitting layer EML-R, EML-G, or EML-B may be spaced apart from the second layer L2. Because the first layer L1 includes an inorganic material, penetration or diffusion of polar materials such as the water (H₂O) and the hydrogen ions (H⁺) may be suppressed. Accordingly, in the positive aging operation in which the movement of the water (H₂O) and the hydrogen ions (H⁺) is facilitated, the water (H₂O) and the hydrogen ions (H⁺) existing in the second layer L2 may be prevented from being moved/diffused to the hole transport area HTR in contact with the first layer L1 through the first layer L1 by the electric field. Thus, damage to the hole transport area HTR due to the water (H₂O) and the hydrogen ions (H⁺) may be reduced or prevented.

In contrast, the second layer L2 may include a liquid-repellent material, and depending on the material characteristics, the second layer L2 may be formed in a porous structure or a low-density amorphous structure. Accordingly, the water (H₂O) and the hydrogen ions (H⁺) may more freely move in the layer than in the first layer L1. Due to the structural characteristics, the water (H₂O) and the hydrogen ions (H⁺) may be more easily moved to the electron transport layer ETL in contact with the second layer L2 in the positive aging operation. Thus, a trap state included in the electron transport layer ETL may be eliminated, and stabilization of moisture management and charge transport may be achieved.

In addition, because the light emitting layer EML-R, EML-G, or EML-B is formed to be spaced apart from the second layer L2 according to some embodiments, the water (H₂O) and the hydrogen ions (H⁺) included in the second layer L2 may not easily move to the light emitting layer EML-R, EML-G, or EML-B, and degradation of the light emitting layer EML-R, EML-G, or EML-B formed of the quantum dots may be prevented or reduced.

According to the present disclosure, the electron transport layer ETL may make contact with the second layer L2 including the liquid-repellent material, the water (H₂O), and the hydrogen ions (H⁺), and the light emitting layer EML-R, EML-G, or EML-B and the hole transport area HTR may be spaced apart from the second layer L2. Accordingly, the water (H₂O) and the hydrogen ions (H⁺) may be induced to selectively move to the electron transport layer ETL, and thus damage to the light emitting layer EML-R, EML-G, or EML-B and the hole transport area HTR due to the water (H₂O) and the hydrogen ions (H⁺) may be reduced or prevented.

FIG. 8 is an enlarged sectional view of the display element layer EDL of the display panel. In the description with reference to FIG. 8, components identical/similar to the components described with reference to FIGS. 4-7 will be assigned with identical/similar reference numerals, and some repetitive description may be omitted.

Referring to FIG. 8, according to some embodiments of the present disclosure, at least a portion of the light emitting layer EML-R, EML-G, or EML-B may make contact with the second layer L2. That is, not only the electron transport layer ETL but also a portion of the light emitting layer EML-R, EML-G, or EML-B may make contact with the second layer L2, and accordingly, the water (H₂O) and the hydrogen ions (H⁺) included in the second layer L2 may move to the light emitting layer as well as the electron transport layer ETL.

In this case, the light emitting layer EML-R, EML-G, or EML-B may also obtain a certain level of stabilization effect due to the water (H₂O) and the hydrogen ions (H⁺) moved from the second layer L2 to the light emitting layer EML-R, EML-G, or EML-B in the positive aging operation. Accordingly, a residual trap state or interface non-uniformity that exists within the luminescent material of the light emitting layer EML-R, EML-G, or EML-B may be resolved. Thus, an initial deviation in light emitting characteristics may be reduced, and the operating stability of the light emitting layer EML-R, EML-G, or EML-B and the durability of the element may be secured.

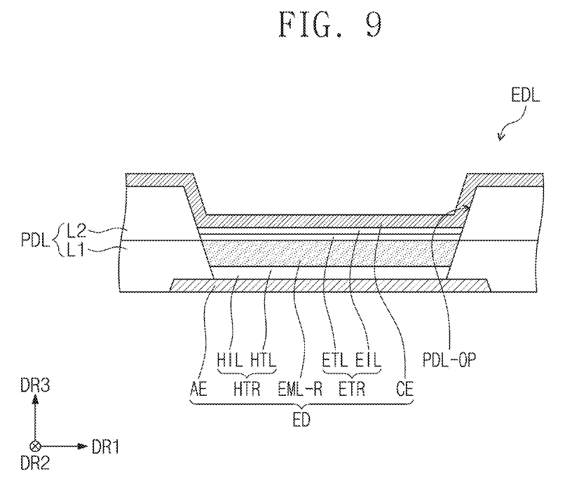

FIG. 9 is an enlarged sectional view of the display element layer of the display panel. In the description with reference to FIG. 9, components identical/similar to the components described with reference to FIGS. 4-8 will be assigned with identical/similar reference numerals, and some repetitive description may be omitted.

Referring to FIG. 9, according to some embodiments of the present disclosure, the electron transport layer ETL and the electron injection layer EIL may be located in the light emitting opening PDL-OP. That is, the electron transport layer ETL and the electron injection layer EIL may have a patterned shape.

Accordingly, unlike in the above-described embodiments, not only the electron transport layer ETL but also the electron injection layer EIL located on the electron transport layer ETL may make contact with the second layer L2, and the water (H₂O) and the hydrogen ions (H⁺) included in the second layer L2 may move to the electron injection layer EIL layer as well as the electron transport layer ETL. In this case, the water (H₂O) and the hydrogen ions (H⁺) introduced into the electron injection layer EIL in the positive aging operation may contribute to organizing a trap state in the electron injection layer EIL or stabilizing an interface state. Thus, an initial deviation in electron injection characteristics may be reduced, and long-term injection efficiency may be secured.

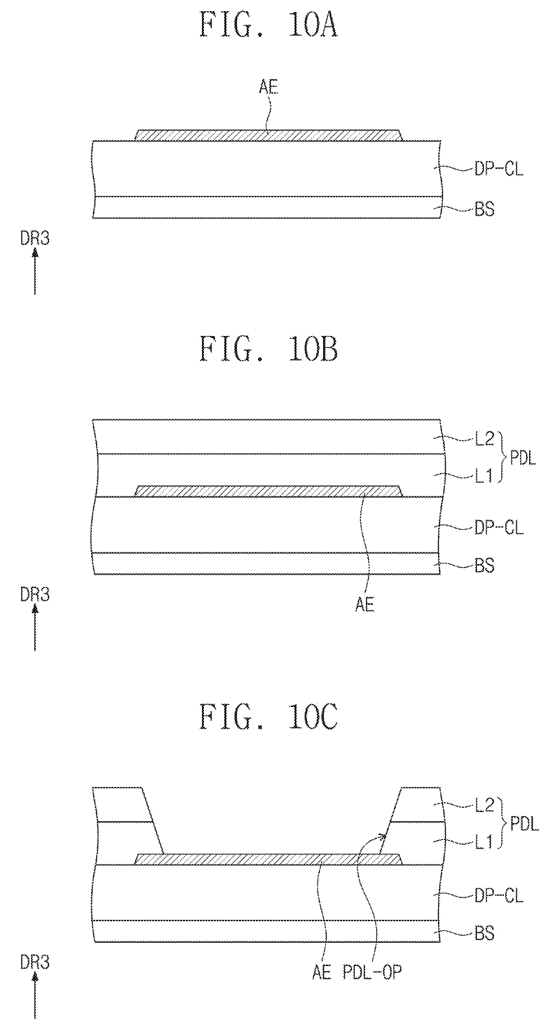

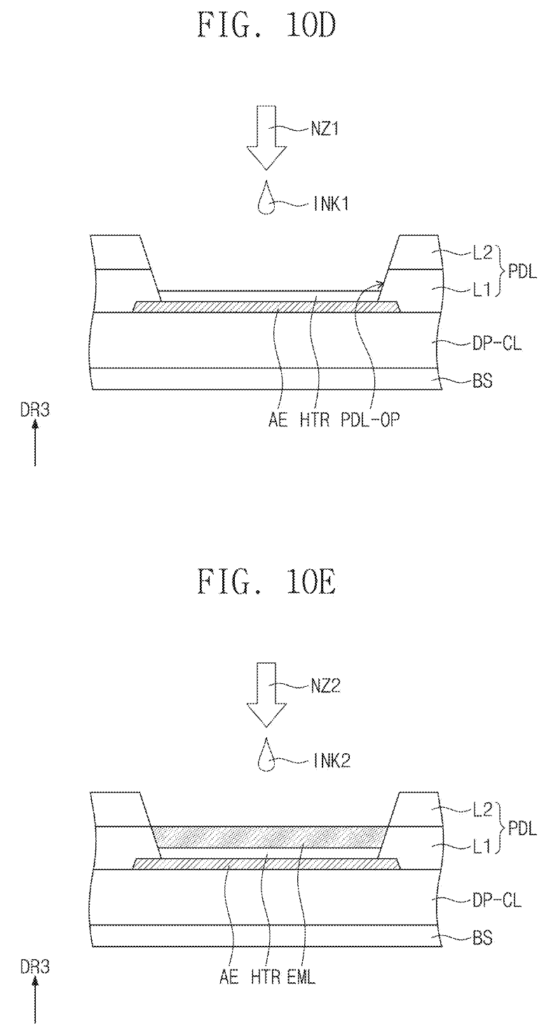

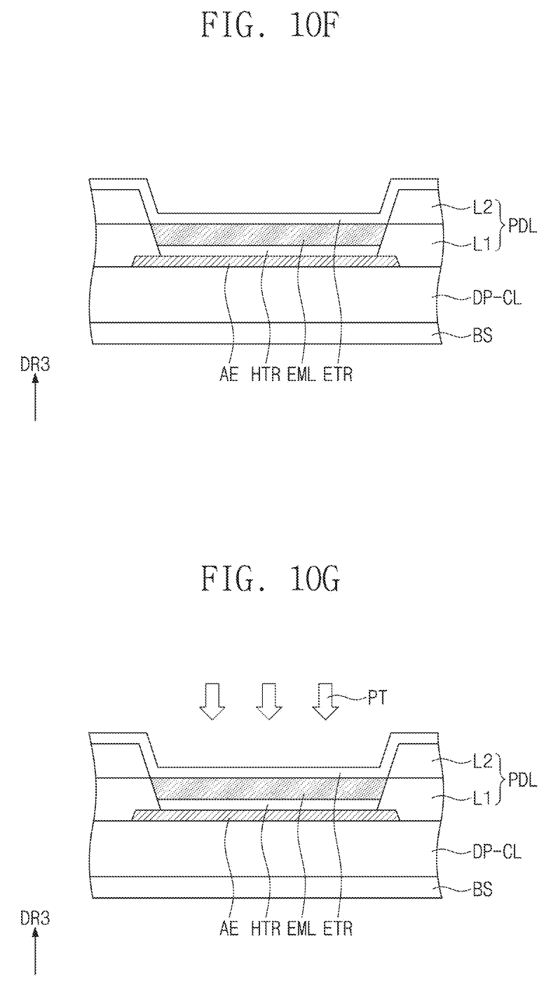

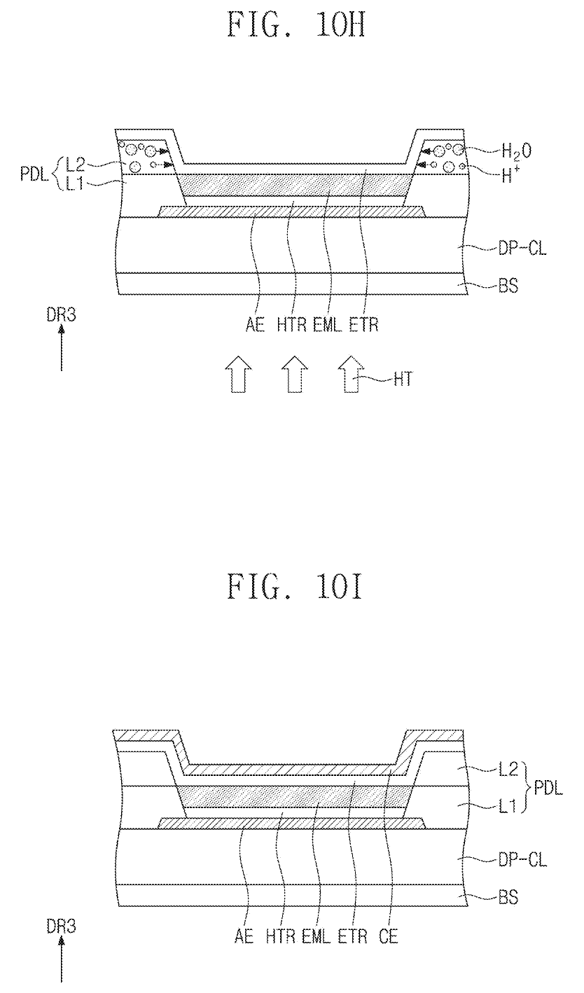

FIGS. 10A-10I are sectional views illustrating some of the operations of a display panel manufacturing method according to some embodiments of the present disclosure. In the description with reference to FIGS. 10A-10I, components identical/similar to the components described with reference to FIGS. 4-9 will be assigned with identical/similar reference numerals, and some repetitive description may be omitted.

Referring to FIG. 10A, the anode AE may be formed on the substrate BS and the circuit element layer DP-CL. According to some embodiments, for ease of description, the circuit element layer DP-CL is illustrated as a single layer, and the elements constituting the circuit element layer DP-CL are omitted.

The anode AE may be formed by coating or depositing a conductive layer on the circuit element layer DP-CL and then making the conductive layer subject to patterning. In this case, the conductive layer may be formed of a single layer or may be formed by sequentially stacking a plurality of layers. For example, the anode AE may be formed by sequentially depositing a first layer formed of ITO, a second layer formed of Al, and a third layer formed of ITO on the entire surface of the circuit element layer DP-CL and then making the first to third layers subject to patterning through a single mask. However, this is illustrative, and the number of layers constituting the anode AE is not limited to any one embodiment.

According to some embodiments, the circuit element layer DP-CL may be formed through a conventional circuit element manufacturing process of forming a semiconductor pattern, a conductive pattern, and a signal line by forming an insulating layer, a semiconductor layer, and a conductive layer by coating or deposition and selectively making the insulating layer, the semiconductor layer, and the conductive layer subject to patterning by a photolithography process and an etching process.

Referring to FIGS. 10B and 10C, the pixel defining layer PDL may be formed by sequentially stacking the first layer L1 and the second layer L2 on the anode AE. In this case, the first layer L1 may be formed by depositing or coating a hydrophilic inorganic material on the anode AE, and the second layer L2 may be formed by depositing or coating a liquid-repellent material including water (H₂O) and hydrogen ions (H⁺).

Thereafter, the light emitting opening PDL-OP may be formed by making the pixel defining layer PDL subject to patterning. For example, according to some embodiments, the light emitting opening PDL-OP may be formed by forming a photoresist layer on the pixel defining layer PDL and then performing an etching process using the photoresist layer as a mask.

Referring to FIGS. 10D and 10E, the hole transport area HTR and the light emitting layer EML may be sequentially formed on the anode AE. In this case, the hole transport area HTR and the light emitting layer EML may be formed through an inkjet process. For example, the hole transport area HTR may be formed in the light emitting opening PDL-OP by dispensing a first ink INK1 onto the anode AE from a nozzle NZ1. The first ink INK1 may include a hole transport material. For example, the first ink INK1 may include PEDOT;PSS, PTAA, NiO, or other organic or inorganic hole transport materials. In addition, the light emitting layer EML may be formed in the light emitting opening PDL-OP by dispensing a second ink INK2 onto the hole transport area HTR from a nozzle NZ2. The second ink INK2 may include quantum dots. For example, CdSe, InP, or perovskite-based quantum dots may be used.

Referring to FIG. 10F, the electron transport area ETR may be formed on the light emitting layer EML. The electron transport area ETR may be deposited on the entire upper surface of the light emitting layer EML. In this case, the electron transport area ETR may be formed of ZnO, TiO, SnO₂, or composite oxide thereof.

In FIGS. 10G and 10H, an operation of performing positive aging of the electron transport area ETR is illustrated. The operation of performing the positive aging of the electron transport area ETR may be performed after the electron transport area ETR is formed on the light emitting layer EML. The corresponding operation may include an operation of applying a solution PT containing an acid material to the pixel defining layer PDL and the electron transport area ETR and an operation of applying heat to the pixel defining layer PDL.

In the operation of applying the solution containing the acid material to the pixel defining layer PDL, the acid material may include at least one of citric acid, malic acid, or ascorbic acid.

As illustrated in FIG. 10H, heat HT may be provided from below the substrate BS to heat the pixel defining layer PDL. For example, a method of placing the substrate BS on a hot plate to transfer heat or performing heat treatment in a chamber may be used.

The movement of the water (H₂O) and the hydrogen ions (H⁺) included in the pixel defining layer PDL may be induced by heat and an electric field generated in the positive aging operation. For example, the water (H₂O) and the hydrogen ions (H⁺) may move toward the electron transport area ETR that makes contact with the second layer L2 including a liquid-repellent material having a relatively low density.

Referring to FIG. 10I, after the positive aging operation, the cathode CE may be deposited on the entire upper surface of the electron transport area ETR. The cathode CE may be formed of, for example, Al, Ag, Mg, or an alloy thereof. However, the material of the cathode CE is not limited thereto.

According to the present disclosure, the pixel defining layer PDL may be formed of a plurality of layers including different materials, for example, the first layer L1 including a hydrophilic inorganic material and the second layer L2 that is located on the first layer L1 and that includes a liquid-repellent material.

Among the layers constituting the light emitting element, a layer that does not require positive aging, for example, the hole transport area HTR may be formed to make contact with the first layer L1, which includes the hydrophilic inorganic material that suppresses the movement of the water (H₂O) and the hydrogen ions (H⁺), so as to minimize damage caused by the water (H₂O) and the hydrogen ions (H⁺).

In contrast, among the layers constituting the light emitting element, a layer that requires positive aging, for example, the electron transport layer ETL (refer to FIG. 6) may be formed to make contact with the second layer L2 including the liquid-repellent material that enables the water (H₂O) and the hydrogen ions (H⁺) to easily move.

Accordingly, a specific layer of the light emitting element that requires positive aging may effectively obtain a stabilization effect, and an influence of a layer that does not require positive aging may be minimized. Thus, the overall reliability of the light emitting element may be relatively improved, an initial deviation in light emitting characteristics may be reduced, and the display panel with relatively improved light efficiency and lifetime characteristics may be provided.

According to some embodiments of the present disclosure, the pixel defining layer may be formed of a plurality of layers including different materials, for example, the first layer including a hydrophilic inorganic material and the second layer that is located on the first layer and that includes a liquid-repellent material.

Among the layers constituting the light emitting element, the layer that does not require positive aging may make contact with the first layer, and the layer that requires positive aging may make contact with the second layer. Accordingly, the overall reliability of the light emitting element may be relatively improved, the initial deviation in the light emitting characteristics may be reduced. Thus, the display panel having relatively improved light efficiency and lifetime characteristics may be provided.

While aspects of some embodiments of the present disclosure have been described with reference to embodiments thereof, it will be apparent to those of ordinary skill in the art that various changes and modifications may be made thereto without departing from the spirit and scope of the present disclosure as set forth in the following claims, and their equivalents.

What is claimed is:

1. A display panel comprising:
a substrate having a display area and a non-display area defined therein;
a circuit element layer on the substrate;
a display element layer on the circuit element layer; and
an encapsulation structure on the display element layer,
wherein the display element layer includes:
a pixel defining layer having a light emitting opening defined therein; and
a light emitting element including an anode, a hole transport area, a light emitting layer including a quantum dot, an electron transport area, and a cathode sequentially stacked one above another,
wherein the pixel defining layer includes a first layer and a second layer on the first layer and including a material different from a material of the first layer, and
wherein the second layer includes water (H₂O) and a hydrogen ion (H⁺).

2. The display panel of claim 1, wherein the second layer includes a liquid-repellent material.

3. The display panel of claim 2, wherein the liquid-repellent material includes a fluorine-based material.

4. The display panel of claim 2, wherein the sum of a thickness of the hole transport area and a thickness of the anode is smaller than a thickness of the first layer.

5. The display panel of claim 4, wherein the light emitting layer is spaced apart from the second layer.

6. The display panel of claim 4, wherein at least a portion of the light emitting layer contacts the second layer.

7. The display panel of claim 4, wherein the hole transport area includes a hole injection layer and a hole transport layer on the hole injection layer,
wherein the electron transport area includes an electron transport layer and an electron injection layer on the electron transport layer, and
wherein the electron transport layer contacts the second layer.

8. The display panel of claim 1, wherein the light emitting opening includes a plurality of light emitting openings, and the plurality of light emitting openings include a first light emitting opening configured to define a first light emitting area configured to emit light of a first color, a second light emitting opening configured to define a second light emitting area configured to emit light of a second color different from the first color, and a third light emitting opening configured to define a third light emitting area configured to emit light of a third color different from the first color and the second color,
wherein the light emitting element includes a plurality of light emitting elements, and the plurality of light emitting elements include a first light emitting element in the first light emitting opening, a second light emitting element in the second light emitting opening, and a third light emitting element in the third light emitting opening, and
wherein a hole transport area of the first light emitting area is in the first light emitting opening, a hole transport area of the second light emitting area is in the second light emitting opening, and a hole transport area of the third light emitting area is in the third light emitting opening.

9. The display panel of claim 8, further comprising:
first to third color filters corresponding to the first to third light emitting elements, respectively.

10. The display panel of claim 1, further comprising:
a sealing member between the substrate and the encapsulation structure to couple the substrate and the encapsulation structure.

11. The display panel of claim 1, wherein the encapsulation structure contacts the cathode.

12. A method for manufacturing a display panel, the method comprising:
forming a circuit element layer on a substrate;
forming an anode on the circuit element layer;
forming, on the anode, a pixel defining layer including a first layer, and a second layer on the first layer and including water (H₂O) and a hydrogen ion (H⁺);
forming a light emitting opening by patterning the pixel defining layer;
sequentially forming a hole transport area, a light emitting layer including a quantum dot, and an electron transport area on the anode;
performing positive aging ofthe electron transport area; and
forming a cathode on the electron transport area,
wherein in performing the positive aging of the electron transport area, the water (H₂O) and the hydrogen ion (H⁺) move from the second layer to the electron transport area.

13. The method of claim 12, wherein performing the positive aging of the electron transport area includes:
applying a solution including an acid material to the pixel defining layer and the electron transport area; and
applying heat to the pixel defining layer such that the water (H₂O) and the hydrogen ion (H⁺) included in the pixel defining layer move toward the electron transport layer.

14. The method of claim 13, wherein the acid material includes at least one of citric acid, malic acid, or ascorbic acid.

15. The method of claim 12, wherein the hole transport area and the light emitting layer are formed through an inkjet process.

16. The method of claim 12, wherein the second layer is formed by depositing or coating a liquid-repellent material.

17. An electronic device comprising:
a display module including a display panel; and
a processor configured to provide image data to the display module,
wherein the display panel includes:
a substrate having a display area and a non-display area defined therein;
a circuit element layer on the substrate;
a display element layer on the circuit element layer; and
an encapsulation structure on the display element layer,
wherein the display element layer includes:
a pixel defining layer having a light emitting opening defined therein; and
a light emitting element including an anode, a hole transport area, a light emitting layer including a quantum dot, an electron transport area, and a cathode sequentially stacked one above another,
wherein the pixel defining layer includes a first layer being lyophilic and a second layer on the first layer, the second layer being liquid repellent, and
wherein the second layer includes water (H₂O) and a hydrogen ion (H⁺).

18. The electronic device of claim 17, wherein the second layer includes a fluorine-based material.

19. The electronic device of claim 18, wherein a sum of a thickness of the hole transport area and a thickness of the anode is smaller than a thickness of the first layer.

20. The electronic device of claim 18, wherein the hole transport area includes a hole injection layer and a hole transport layer on the hole injection layer,
wherein the electron transport area includes an electron transport layer and an electron injection layer on the electron transport layer, and
wherein the electron transport layer contacts the second layer.
